(19) United States
(12) Patent Application Publication
(10) Pub. No.: US 2010/0025782 A1
(43) Pub. Date: Feb. 4, 2010

(54) TECHNIQUE FOR REDUCING SILICIDE NON-UNIFORMITIES IN POLYSILICON GATE ELECTRODES BY AN INTERMEDIATE DIFFUSION BLOCKING LAYER

(76) Inventors: Uwe Griebenow, Markkleeberg (DE); Kai Frohberg, Niederau (DE); Kerstin Ruttloff, Hainichen (DE)

Correspondence Address: WILLIAMS, MORGAN & AMERSON, 10333 RICHMOND, SUITE 1100, HOUSTON, TX, 77042, US

(21) Appl. No.: 12/464,917

(22) Filed: May 13, 2009

(30) Foreign Application Priority Data
Jul. 31, 2008 (DE) 10 2008 035 809.6

(51) Int. Cl. H01L 29/49; H01L 21/28

(52) U.S. Cl. 257/413; 438/592; 257/E21.19; 257/E29.155

(57) ABSTRACT

Threshold variability in advanced transistor elements, as well as increased leakage currents, may be reduced by incorporating a barrier material in a polysilicon gate electrode. The barrier material results in a well-controllable and well-defined metal silicide in the polysilicon gate electrode during the silicidation sequence and during the further processing by significantly reducing the diffusion of a metal species, such as nickel, into the vicinity of the gate dielectric material.

### BACKGROUND OF THE INVENTION

1. Field of the Invention

Generally, the present disclosure relates to the field of fabrication of integrated circuits, and, more particularly, to semiconductor devices having metal silicide portions on semiconductor regions to reduce the resistance of the semiconductor regions.

2. Description of the Related Art

In modern ultra-high density integrated circuits, device features are steadily decreasing to enhance device performance and functionality. Shrinking the feature sizes, however, entails certain problems that may partially offset the advantages obtained by the reduced feature sizes. Generally, reducing the feature sizes of, for example, a transistor element may lead to a decreased channel resistance in the transistor element and thus result in a higher drive current capability and enhanced switching speed of the transistor. When reducing the features sizes of these transistor elements, however, the increasing electrical resistance of conductive lines and contact regions, i.e., of regions that connect transistor areas, such as drain and source regions, with the periphery of the transistor element, becomes a dominant issue, since the cross-sectional area of these lines and regions also decreases when scaling the feature sizes. The cross-sectional area, however, determines, in combination with the characteristics of the material comprising the conductive lines and contact regions, the resistance of the respective line or contact region.

The above problems may be of particular interest for a typical critical feature size in this respect, also referred to as a critical dimension (CD), such as the extension of the channel of a field effect transistor that forms in a semiconductor region positioned adjacent to a gate electrode between a source region and a drain region of the transistor. Reducing this extension of the channel, commonly referred to as channel length, may significantly improve device performance with respect to fall and rise times of the transistor element, due to the smaller capacitance between the gate electrode and the channel and due to the decreased resistance of the shorter channel. Shrinking the channel length, however, also entails the reduction in size of any conductive lines, such as the gate electrode of the field effect transistor, which is frequently formed on the basis of polysilicon, and the contact regions that allow electrical contact to the drain and source regions of the transistor, so that consequently the available cross-section for charge carrier transportation is reduced. As a result, the conductive lines and contact regions exhibit a higher resistance unless the reduced cross-section is compensated for by improving the electrical characteristics of the material forming the lines and contact regions, such as the gate electrode and the drain and source contact regions.

It is thus of particular importance to improve the characteristics of conductive regions that are substantially comprised of semiconductor material, such as silicon. For instance, in modern integrated circuits, the individual semiconductor devices, such as field effect transistors, capacitors and the like, are primarily based on silicon, wherein the individual devices are connected by silicon lines in the device level, i.e., the silicon layer, and metal lines in one or more metallization layers. While the resistivity of the metal lines may be improved by replacing the commonly used aluminum with, for example, copper and copper alloys, process engineers are confronted with a challenging task when an improvement in the electrical characteristics of silicon-containing semiconductor lines and semiconductor contact regions is required.

To this end, frequently, the silicon-containing device areas, such as the gate electrodes and the drain and source regions, may be treated to obtain a metal silicide which may have a significantly enhanced conductivity compared to even highly doped silicon regions. Hence, a plurality of refractory metals, such as titanium, cobalt, nickel, platinum and the like, may typically be used, depending on the overall device requirements and feature sizes, in order to reduce sheet resistivity and contact resistivity in semiconductor devices. Although sophisticated manufacturing techniques are available for forming a metal silicide in gate electrodes and drain and source regions in a self-aligned manner, it turns out that, in advanced semiconductor devices, significant device variations may be observed, which may be associated with non-uniformities of a metal silicide in polysilicon gate electrodes, as will be described in more detail with reference to FIGS. 1a-1c.

FIG. 1a schematically illustrates a cross-sectional view of a semiconductor device 100 including a substrate 101, which may represent a silicon substrate, in which is formed a field effect transistor 110 of a specified conductivity type, such as an N-channel transistor or a P-channel transistor. The transistor 100 is formed in and above a semiconductor layer 102, i.e., a silicon-containing material, which may be formed above the substrate 101, possibly in combination with an intermediate or buried insulating layer (not shown). The semiconductor layer 102 may comprise respective isolation structures 103, such as shallow trench isolations, which may define respective active regions for forming therein one or more circuit elements, such as the transistor 110. An active region is to be understood as a semiconductor region comprising or receiving a specific dopant profile in order to appropriately pattern the overall conductivity therein. The transistor 110 comprises a gate electrode 115 formed on a gate insulation layer 118, which separates the gate electrode 115 from the semiconductor layer 102. Furthermore, a spacer structure 116 comprised of, for instance, silicon dioxide or silicon nitride, possibly in combination with a liner material 116A, is formed at sidewalls of the gate electrode 115. Moreover, the transistor 110 comprises source and drain regions 114, including respective extensions 114A, which have an appropriate lateral dopant concentration as required to connect to a channel region 111, in which a conductive channel builds up between the drain and source regions 114 upon application of an appropriate control voltage to the gate electrode 115. As previously discussed, the gate length of the transistor element 110, indicated as 115L, determines the channel length of the transistor 110 and, therefore, as previously pointed out, significantly affects the electrical characteristics of the transistor 110. A reduced gate length and thus a reduced overall dimension of the transistor 110 typically results in an increased resistance of the gate electrode 115 and contact areas of the drain and source regions 114, although these regions are typically heavily doped. Furthermore, the general electrical behavior of the transistor 110 is also determined by the capacitive coupling between the gate electrode 115 and the channel region 111, which, in combination with the electronic characteristics of the gate electrode material, such as the work function thereof, may finally determine the threshold voltage of the transistor 110, i.e., the voltage between the gate electrode 115 and the source terminal, upon which a conductive channel builds up in the channel region 111. For example, in general, a reduced threshold voltage of a transistor element may result in a higher drive current capability for otherwise identical characteristics. That is, for identical dimensions, such as gate length, channel length, thickness and composition of the gate insulation layer 118, a variation of the threshold voltage, for instance caused by non-uniformities in the composition of the gate electrode material, may result in a significant variation of the operational behavior of the transistors under consideration. Respective differences in transistor operation may, however, be unacceptable in sophisticated semiconductor devices, for instance in device areas including memory cells such as static RAM (random access memory) cells in which a certain degree of operational stability of the transistor elements may be required in order to obtain a reliable mechanism for storing information.

Furthermore, in the manufacturing stage shown, a layer of refractory metal 105 may be formed, at least above the gate electrode 115 and, depending on the overall process strategy, also above the drain and source regions 114, if a process is to be carried out so as to commonly provide a metal silicide in the gate electrode 115 and the drain and source regions 114. In advanced semiconductor devices, frequently, nickel may be used for forming the layer 105, possibly in combination with other components, such as platinum and the like, which may provide enhanced conductivity compared to other refractory materials, such as cobalt, titanium and the like.

The semiconductor device 100 as shown in FIG. 1a may be formed on the basis of well-established process techniques, for instance comprising the following steps. After forming the isolation structure 103 by well-known photolithography, etch and deposition techniques, implantation steps may be performed to create a required vertical dopant profile in the semiconductor layer 102. Subsequently, the gate insulation layer 118 is formed, for instance by deposition, oxidation and the like, according to design requirements. Next, the gate electrode 115 is formed by patterning, for instance, a polysilicon layer by means of sophisticated photolithography and etch techniques. Then, a further implantation step for forming the source and drain extension regions 114A within the source and drain regions 114 is performed and the spacer structure 116 is patterned in accordance with requirements in view of the lateral profile of the drain and source regions 114. That is, the spacer structure 116 may be used as an implantation mask during an implantation sequence, which may include a plurality of individual implantation steps, depending on the complexity of the overall dopant profile. In FIG. 1a, a single implantation step may be used on the basis of the spacer structure 116 as shown in order to obtain the drain and source regions 114. There-after, an appropriate sequence for preparing the gate electrode 115 and/or the drain and source regions 114 for receiving a metal silicide may be performed in accordance with any appropriate device strategy. In the example shown in FIG. 1a, for instance, a specified implantation process may be performed after annealing and thus activating the dopants in the drain and source regions 114 and the gate electrode 115 in order to produce a certain degree of lattice damage in the drain and source regions, which may allow a control of a subsequent diffusion activity of metal atoms of the refractory metal 105. Furthermore, well-established cleaning processes may be performed in order to remove contaminants and to condition exposed surface portions of the gate electrode 115 and the drain and source regions 114. Thereafter, the layer 105 may be deposited, for instance, by physical vapor deposition, chemical vapor deposition and the like, with an appropriate thickness selected in accordance with well-established recipes so as to adjust the amount of metal silicide to be created in the gate electrode 115 and the drain and source regions 114.

FIG. 1b schematically illustrates the semiconductor device 100 during a heat treatment 106, which may include any appropriate anneal technique, such as laser-based processes, flashlight-based processes, conventional rapid thermal anneal processes and the like, in which an appropriate process temperature may be established in order to initiate the chemical reaction of metal in the layer 105 and the silicon material in the gate electrode 115 and/or the drain and source regions 114. As previously indicated, in view of enhancing overall conductivity, frequently, nickel may be used as a viable candidate for the refractory metal 105, which may form a nickel silicide composition at temperatures from approximately 200-400° C. with a desired high conductivity. Generally, in view of enhancing transistor performance with respect to a reduction of signal propagation delay, an increased amount of nickel silicide may be desirable in the gate electrode 115 so that the overall line resistance may be maintained at a low level, even though the cross-sectional area of the gate electrode 115 may be reduced for device generations including a gate length of approximately 50 nm and less. Similarly, a high conductivity is desirable in the drain and source regions 114, wherein, however, a depth of a respective metal silicide region may be selected in accordance with the overall dopant profile to reduce the probability of creating any enhanced leakage paths or shorts between the drain and source regions 114 or the extensions 114A and the channel region 111. For example, by substantially amorphizing the drain and source regions down to a specific depth, a certain degree of control of the diffusion activity during the heat treatment 106 may be achieved, since nickel may exhibit a significantly different diffusion and reaction behavior in a substantially amorphized area compared to a substantially crystalline lattice material. Consequently, the diffusivity of nickel in the gate electrode 115 may be increased compared to a crystalline material, due to the polycrystalline nature of the gate electrode material, while additionally, typically, any pre-amorphization implantations may also affect an upper portion of the gate electrode 115, thereby further increasing the diffusivity of the nickel during the treatment 106. In principle, an increased penetration and thus creation of conductive nickel silicide in the gate electrode 115 may be desirable, wherein, however, any process non-uniformities may contribute to variations in the operational behavior due to threshold variations and increased leakage currents, as will be explained with reference to FIG. 1c.

FIG. 1c schematically illustrates the semiconductor device 100 after the silicidation sequence, i.e., after the heat treatment 106 (FIG. 1b), initiating a chemical reaction between the nickel material of the layer 105 and exposed silicon areas and a removal of any non-reacted metal material, for instance from the spacer structure 116 and the isolation structures 103 and from other areas, such as the drain and source regions 114, if the respective material of the layer 105 may not entirely be consumed due to a reduced desired thickness of the corresponding metal silicide. As shown, the device 100 comprises metal silicide regions 117 in the drain and source regions 114 having a depth in accordance with design requirements, wherein also, in principle, a distance of the metal silicide regions 117 from the channel region 111 is determined by the width of the spacer structure 116. Similarly, a metal silicide region 119 is formed in the gate electrode 115, in which the concentration of nickel may vary with a height of the gate electrode 115. That is, during the silicidation process, which may also include a thermal treatment for stabilizing the overall material characteristics and the like, a more or less pronounced concentration gradient 119A with respect to nickel may be created. As previously explained, in general, an increased amount of nickel silicide within the gate electrode 115 may be desirable with respect to enhancing overall conductivity, wherein, however, in view of threshold stability, a substantially metal-free area of polysilicon should be maintained immediately adjacent to the gate insulation layer 118, since otherwise a significant change in threshold voltage may be caused due to the different electronic characteristics of nickel silicide compared to doped polysilicon material. However, since the presence of nickel in the vicinity of the gate insulation layer 118 and thus the height level to which the metal silicide region 119 extends may depend on the previously performed silicidation sequence including one or more heat treatments, a certain degree of variability of the gradient 119A and thus of the respective threshold voltages may be observed. Further-more, nickel or nickel silicide in contact with the gate insulation layer 118 may cause a degradation of the dielectric material and may finally result in increased leakage currents. As a pronounced threshold voltage variability may represent a severe issue for a plurality of transistors, such as static RAM cells, enhanced leakage currents caused by gate dielectric degradation may reduce performance of any type of transistors, thereby contributing to reduced production yield and profitability of the corresponding manufacturing sequence.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and techniques for forming the same in which enhanced control of the diffusion activity of a metal species, such as nickel, may be achieved when forming a metal silicide in a silicon-containing gate electrode structure. The enhanced control of the diffusion activity may be accomplished by incorporating a diffusion hindering material layer, which may also be referred to as a barrier layer, which, upon contact with a metal material, such as nickel and the like, may significantly slow down the thermal motion of the metal atoms towards the gate insulation layer, thereby significantly reducing the probability of positioning a metal, such as nickel, in the vicinity of the gate insulation layer. Consequently, a variability of threshold voltages of transistor elements caused by a material of different work function in immediate contact with the gate insulation material may be reduced, while also the risk of creating damage and thus increased leakage currents due to the presence of specific metal species may also be reduced. Therefore, a well-controllable enhancement of the gate electrode conductivity may be achieved, substantially without increasing the risk of pronounced yield losses.

One illustrative semiconductor device disclosed herein comprises a silicon-containing gate electrode formed above at least a semiconductor region, wherein the silicon-containing gate electrode comprises a first layer comprised of polysilicon and a second layer comprising a metal silicide material. Furthermore, the first and second layers are separated by a barrier material. Additionally, the semiconductor device comprises an insulation layer positioned between the silicon-containing gate electrode and the semiconductor region.

One illustrative method disclosed herein comprises identifying a target depth of a metal silicide region to be formed in a silicon-containing gate electrode. Furthermore, the silicon-containing gate electrode is formed above a semiconductor region so as to include a barrier material at the target depth. Additionally, the method comprises forming the metal silicide region in the silicon-containing gate electrode based on the barrier material.

A further illustrative method disclosed herein comprises forming a layer stack above at least a semiconductor region, wherein the layer stack comprises a first silicon-containing layer, a second silicon-containing layer formed above the first silicon-containing layer and a barrier layer positioned between the first and second silicon-containing layers. The method further comprises forming a gate electrode from the layer stack and forming a metal silicide in the gate electrode.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of a semiconductor device including a transistor element during various manufacturing stages in forming a metal silicide region in a polysilicon gate electrode, according to conventional strategies;

FIG. 2a schematically illustrates a cross-sectional view of a semiconductor device in an early manufacturing stage in which a target depth for a diffusion hindering material or barrier material may be selected in a silicon-containing electrode material, according to illustrative embodiments;

FIGS. 2b-2d schematically illustrate cross-sectional views during various manufacturing stages in forming a layer stack of a gate electrode material including a barrier material at a specified target depth, in accordance with further illustrative embodiments;

FIGS. 2e-2f schematically illustrate cross-sectional views of the transistor element including a patterned gate electrode having formed therein a barrier material, according to further illustrative embodiments; and

FIGS. 2g-2h schematically illustrate cross-sectional views of a silicon-containing gate electrode material in which a barrier layer may be positioned on the basis of surface treatments and/or ion implantation, according to still further illustrative embodiments.

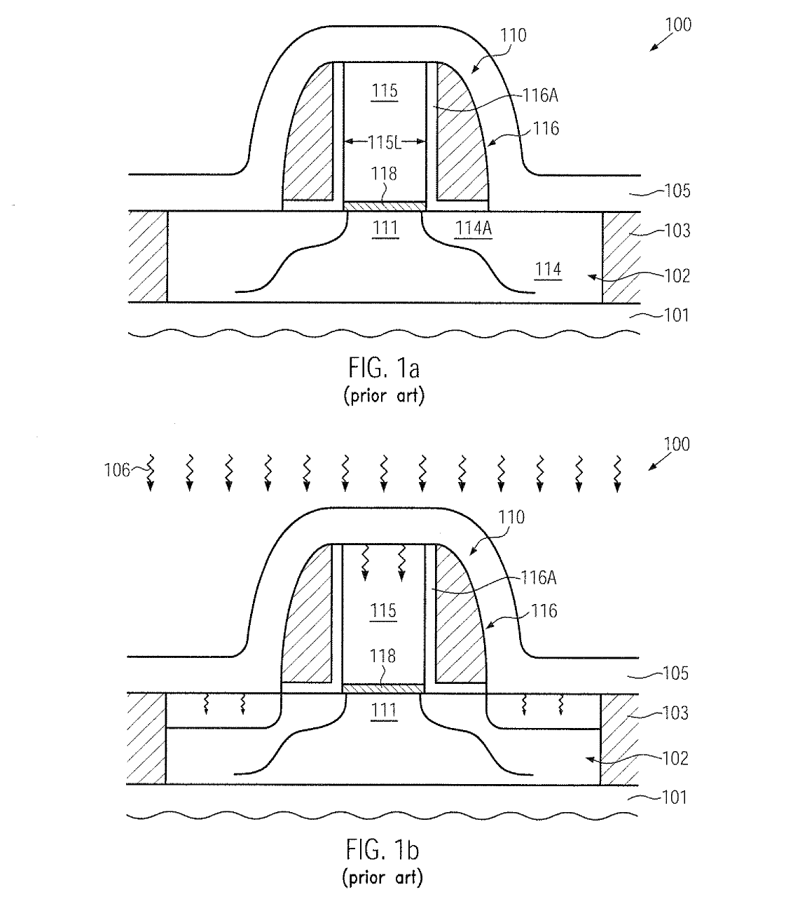

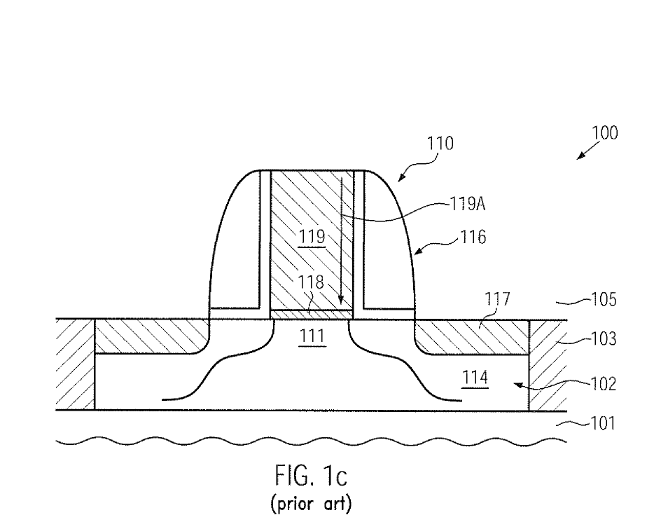

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to techniques and semiconductor devices in which variability in transistor performance and leakage currents may be reduced by focusing on the influence of the silicidation process on overall transistor behavior. To this end, the present disclosure contemplates the relation between the concentration of metal atoms in the vicinity of the gate insulation layer and respective threshold variations and enhanced leakage currents in advanced transistor elements. In some illustrative aspects disclosed herein, enhanced control of the silicidation process in silicon-containing gate electrode materials may be accomplished by positioning an appropriate material for reducing the diffusion activity of a metal species during respective heat treatments performed during the silicidation sequence and any processes used during the further manufacturing sequence. The barrier material, which is to be understood as material which may generally exhibit a reduced diffusion activity when provided within a silicon-containing gate electrode material, may therefore efficiently reduce the amount of metal that may penetrate through the barrier material during and after the silicidation process. On the other hand, the barrier material may itself have substantially no effect with respect to the overall transistor characteristics, for instance in view of threshold variation, or the barrier material may be selected in combination with the silicon-containing gate electrode material and the specific dopant concentration contained therein such that a desired threshold voltage may be achieved. Since the vertical position of the barrier material within the silicon-containing gate electrode material may be defined by well-established deposition techniques, a significantly reduced process-induced variation of the resulting transistor characteristics may be achieved compared to moderately pronounced non-uniformities encountered in conventional strategies, in which the final metal gradient may be determined by one or more heat treatments. Furthermore, in some illustrative aspects, the barrier material or diffusion hindering material may not negatively affect the overall conductivity or may even enhance the overall conductivity when the barrier material is provided in the form of a metal-containing material having increased conductivity compared to a corresponding metal silicide material, such as nickel silicide and the like.

In still other illustrative aspects disclosed herein, enhanced control of the silicidation process, i.e., of the diffusion of a metal species, may be accomplished by providing the barrier layer in the form of any appropriate inhomogeneities within a silicon-containing gate electrode material in order to establish an area or zone of significantly different diffusion characteristics with respect to the metal species under consideration. For instance, during the deposition of the silicon-containing gate electrode material, the surface of a corresponding sub-layer may be appropriately treated, for instance, by plasma or general ion bombardment, oxidation, nitridation and the like, in order to achieve a desired barrier with respect to the diffusion activity. Thereafter, the remaining material of the gate electrode may be deposited and may be processed in accordance with process requirements. Also, in this case, conductive areas may be provided while also initially insulating barrier layers may be provided, which may be “disrupted” during the silicidation process, however in a highly controllable manner so that, in total, overall process uniformity during the silicidation process and thus of the corresponding metal silicide may be enhanced. In other cases, an appropriate modification of a zone within the silicon-containing gate electrode material may be accomplished by ion implantation, thereby providing the “barrier” layer after the deposition of at least a significant amount of the gate electrode material. Also, in this case, enhanced overall uniformity of the corresponding metal silicide may be obtained. It should be appreciated that the principles disclosed herein may be advantageously applied to sophisticated semiconductor devices in which a gate length of 50 nm and significantly less, such as 30 nm and less, may be required by the corresponding design rules, since typically the increased packing density associated with the overall reduced device dimensions may provide a high density of transistor elements provided at device areas of significantly different neighborhoods, such as densely packed transistors compared to moderately isolated devices, so that, locally, different process conditions may be encountered in the various device regions. Consequently, in combination with the process fluctuations generally occurring in the context of heat treatments during a silicidation process, sophisticated overall device geometries may also contribute to additional device variability of otherwise identical transistor structures. Consequently, in this case, enhanced process uniformity during a process sequence, which may have a significant influence on threshold voltage and leakage current behavior, may therefore directly translate into enhanced production yield and performance of the semiconductor device under consideration. On the other hand, the principles disclosed herein may also be readily applied to less critical applications, thereby also benefiting from enhanced process uniformity and thus production yield. For this reason, the present disclosure should not be considered as being restricted to specific critical device dimensions, unless such restrictions are specifically set forth in the claims and in embodiments of the specification.

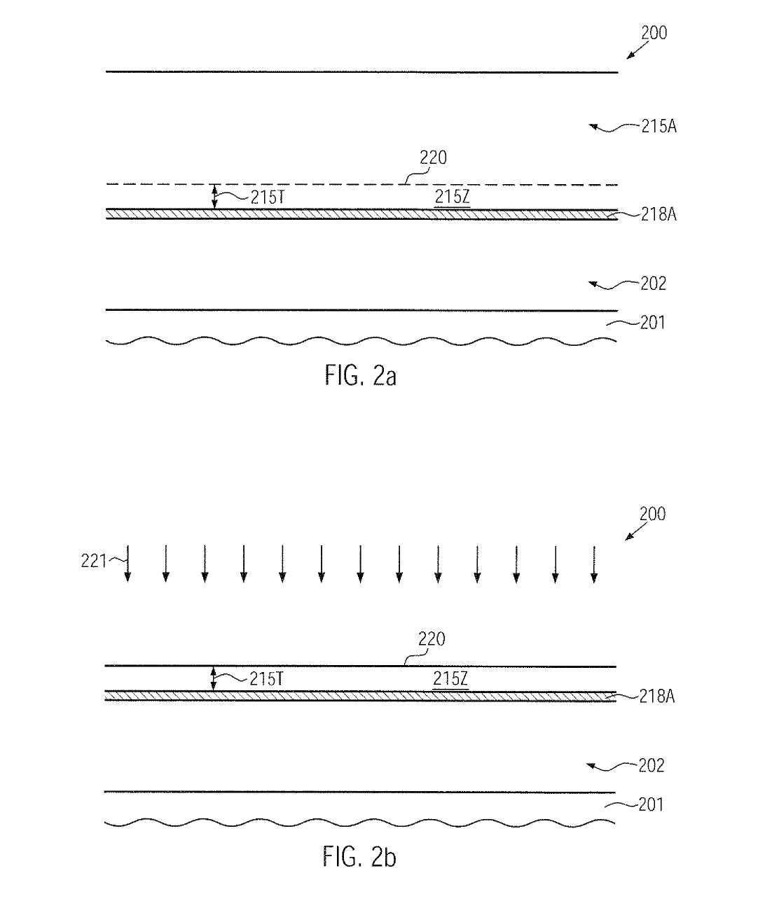

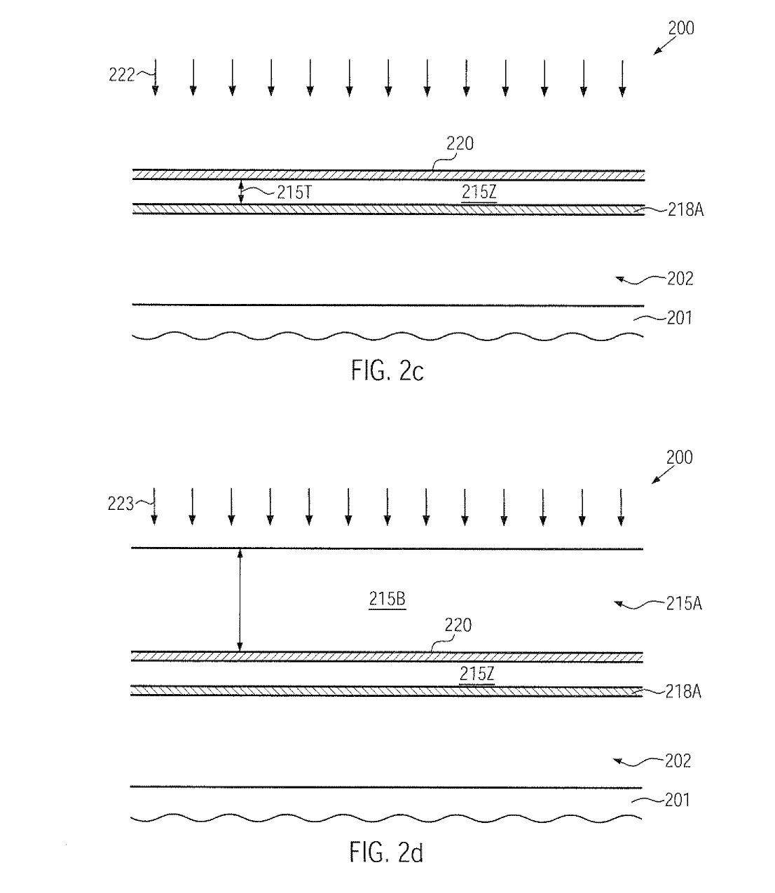

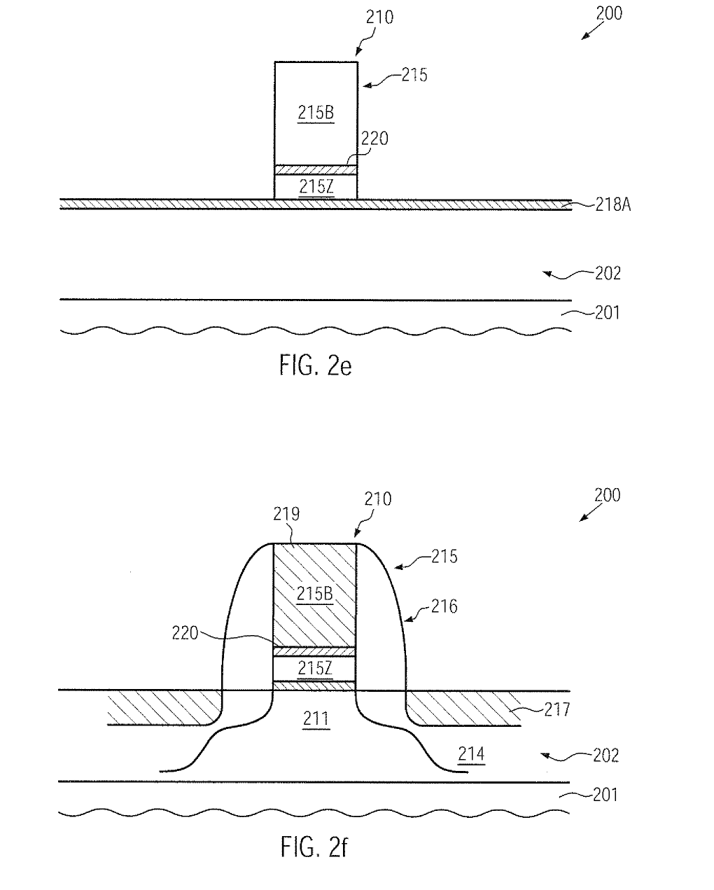

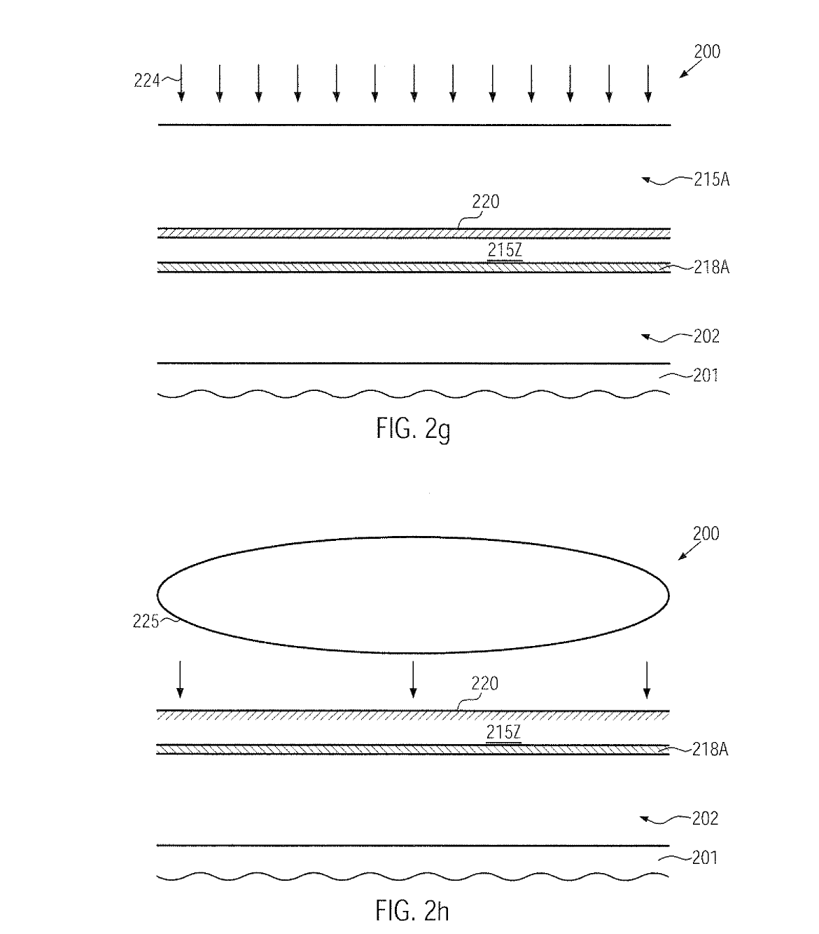

FIG. 2a schematically illustrates a cross-sectional view of a semiconductor device 200 at an early manufacturing stage. As illustrated, the device 200 may comprise a substrate 201, above which may be formed a semiconductor layer 202, such as a silicon-containing layer and the like, wherein it should be appreciated that the semiconductor layer 202 may comprise any other appropriate components, such as germanium, carbon, corresponding dopant species and different concentrations and types and the like, as are required for the further processing of the device 200. Furthermore, the substrate 201, in combination with the semiconductor layer 202, may represent a “bulk” configuration, i.e., the semiconductor layer 202 may be in direct contact with a crystalline material portion of the substrate 201, while, in other cases, an intermediate or buried insulating layer (not shown) may be formed between the substrate 201 and the semiconductor layer 202, at least locally within the device 200, thereby forming a silicon-on-insulator (SOI) configuration. It should be appreciated that the semiconductor layer 202, or at least an upper portion thereof, may comprise appropriately positioned isolation structures (not shown), as are, for instance, previously explained with reference to the device 100, in order to define respective active regions in the semiconductor layer 202 in order to form therein and thereabove circuit elements such as transistors, capacitors and the like. Moreover, in the manufacturing stage shown, a silicon-containing gate electrode material 215A may be formed above the semiconductor layer 202 and above respective isolation structures, wherein the silicon-containing layer 215A, in one illustrative embodiment, may be comprised of polysilicon material, which may include, if required, any appropriate dopant species. It should be appreciated that, in the manufacturing stage shown, the layer 215A may comprise different types of dopants, for instance an N-type dopant when provided above active regions dedicated to N-channel transistors, while, in active regions of P-channel transistors, a P-dopant species may be incorporated in the layer 215A. Consequently, above corresponding isolation structures, respective PN junctions may be provided in a more or less pronounced manner, depending on the process strategy for providing an appropriate dopant species in the gate electrode layer 215A. It should further be noted that a silicon-containing material is to be understood as any material which may comprise a significant amount of silicon so as to support a silicidation process in a later manufacturing stage. For example, the layer 215A may also comprise other material components, such as germanium and the like, depending on the overall device requirements. Typically, a thickness of the gate electrode layer 215A may be selected in accordance with the process strategy and the device requirements, that is, the gate electrode material 215A may have to provide an appropriate ion blocking effect during a later manufacturing stage, in which drain and source regions may be formed in the semiconductor layer 202 on the basis of ion implantation processes. In other cases, additional materials may be formed above the gate electrode material 215A so as to obtain a required height of an implantation mask to be formed from the material 215A, wherein the actual thickness of the layer 215A may be less compared to a desired depth of drain and source regions to be provided in the semiconductor layer 202.

Furthermore, in the manufacturing stage shown, a gate dielectric material 218A may be provided between the electrode material 215A and the semiconductor layer 202. As previously explained, for sophisticated semiconductor devices, a reduced thickness in the range of one to several nm may be used for the gate dielectric material 218A, thereby rendering this material highly sensitive with respect to leakage currents and the like, which may be caused by the presence of a metal species, as previously explained. The gate dielectric material 218A may comprise any appropriate material, such as silicon dioxide-based materials, silicon nitride, high-k dielectric materials, which are to be understood as materials having a dielectric constant of 10.0 or higher. For example, hafnium oxide, zirconium-based materials and the like may be used as high-k dielectric materials which may be used, possibly in combination with extremely thin conventional dielectrics, in order to obtain the desired transistor characteristics.

Furthermore, as illustrated, a target height or depth 215T may be selected within the material 215A, wherein the height level defined by 215T may correspond to a zone within the gate electrode material 215A in which a significantly reduced amount of metal is to be encountered in a later manufacturing stage after performing a silicidation process. Thus, the target height level 215T may be selected such that the desired transistor characteristics in view of threshold voltage may be achieved on the basis of the material characteristics of the layer 215A without significant interference of any metal species used during the formation of metal silicide regions. For example, the target height level 215T may be selected to be approximately 1-10 nm in sophisticated applications, wherein the height level 215T may also depend on the diffusion blocking effect of a “barrier” layer 220, which may have to be formed within the material 215A at the height level 215T. That is, the barrier layer 220 may represent any appropriate material or zone within the layer 215A, which may effect a significant reduction of the diffusion activity of a metal species moving towards the gate dielectric layer 218A during a silicidation process. It should be appreciated that, in some illustrative embodiments, the barrier layer 220 may represent a layer of any discontinuities or inhomogeneities within the layer 215A, which may reduce the overall diffusion activity of the metal species under consideration. For instance, a high dopant gradient between the layer 220 and the material within a zone 215Z, defined by the target height 215T, may represent a barrier layer when the corresponding dopant gradient may contribute to a reduced diffusion of metal into the zone 215Z. For example, the barrier layer 220 may represent a layer of increased concentration of an inert dopant species, such as xenon and the like, while, in other cases, an electrically active dopant species may be locally provided with high concentration so as to obtain a corresponding dopant gradient with respect to the zone 215Z. Corresponding manufacturing techniques and other examples for a barrier layer 220 based on an increased dopant concentration will be described later on. In other cases, the barrier layer 220 may represent a material of different composition compared to the material of the zone 215Z, thereby providing the desired diffusion blocking effect.

The semiconductor device 200 as shown in FIG. 2a may be formed on the basis of the following processes. Generally, in some approaches, for a given transistor configuration, i.e., for given critical dimensions such as gate length, gate height and the like, the target height level 215T may be selected in view of obtaining a desired high conductivity of a gate electrode to be formed from the material 215A, while nevertheless providing uniform threshold voltage characteristics, which may be adjusted on the basis of the well-defined material composition and dopant concentration in the zone 215Z. Furthermore, the height level 215T may also be selected by considering the diffusion blocking capability of the barrier layer 220. That is, for a highly efficient barrier material such as titanium nitride, tungsten, tantalum, tantalum nitride, titanium and the like, the height level 215T may be selected less compared to other barrier layers, such as barrier layers formed on the basis of implantation species and the like, where the diffusion blocking effect may be less pronounced. It should be appreciated that a corresponding diffusion blocking effect of various types of barrier layers 220 may readily be determined on the basis of test measurements in which various types of barrier layers 220 may be tested during and after a silicidation process, for instance by measuring the amount of a corresponding metal component, such as nickel, for a given silicidation sequence. Respective measurements may be obtained by well-established metrology strategies, for instance by using cross-sectional analysis techniques and the like. Consequently, on the basis of respective measurements, the target height level 215T may be selected for one or more product types and one or more process strategies.

The gate dielectric material 218A may be formed by any appropriate technique, which may include oxidation and/or deposition and/or surface treatment, as may be required for the device 200 under consideration. Next, the gate electrode material 215A may be formed such that the barrier layer 220 may be provided on the basis of the previously selected target height level 215T. As will be described later on in more detail, the barrier layer 220 may be obtained by deposition, surface treatment, ion implantation and the like.

With reference to FIGS. 2b-2d, a manufacturing sequence may be described in which the barrier layer 220 may be formed by deposition.

FIG. 2b schematically illustrates the device 200 in which material of the zone 215Z may be deposited on the gate dielectric material 218A, wherein a thickness of the zone 215Z may correspond to the previously selected target height level 215T. For this purpose, well-established deposition recipes may be used, for instance low pressure chemical vapor deposition (CVD), in order to form the zone 215Z as a polysilicon material, which may possibly comprise other components, such as germanium and the like, wherein, also, depending on the overall process strategy, a certain concentration of dopant species may be incorporated. The dopant species, if required, may be incorporated during the deposition process 221 wherein, as previously explained, after forming the zone 215Z for one type of active region, unwanted material from another type of active region may be removed and subsequently an appropriately doped material may be deposited during the process sequence 221, followed by a planarization process, such as chemical mechanical polishing (CMP) and the like, thereby obtaining two differently doped zones 215Z, wherein the dopant concentration may be adjusted on the basis of deposition parameters during the sequence 221. In other cases, an appropriate dopant concentration may be established after the deposition process 221 by ion implantation and the like. In still other illustrative embodiments, the material of the zone 215Z may be deposited as a substantially intrinsic silicon-containing material, wherein the desired dopant concentration in the zone 215Z may be established after completing the gate electrode material 215A (see FIG. 2a) on the basis of an appropriate implantation process.

FIG. 2c schematically illustrates the semiconductor device 200 during a further deposition process 222 designed to form the barrier layer 220. For example, the deposition process 222 may represent any appropriate deposition technique, such as physical vapor deposition, chemical vapor deposition and the like, in which an appropriate barrier material may be deposited. In some illustrative embodiments, the barrier layer 220 may comprise a metal which may be provided in a substantially pure form or in addition to other components, such as nitrogen, so as to obtain the desired diffusion blocking effect. For example, titanium, titanium nitride, tantalum, tantalum nitride, tungsten and the like may represent appropriate candidates for the barrier layer 220. It should be appreciated that the barrier layer 220 itself may have a reduced degree of diffusivity within the zone 215Z at temperatures which may be used during the further processing of the device 200. That is, the barrier layer 220 may remain “localized” to a desired high degree at the height level 215T during subsequent high temperature processes, which may typically be performed in activating dopant species for drain and source regions still to be formed in the semiconductor layer 202. For example, the above-identified materials or material compositions may exhibit the desired behavior so that the finally achieved transistor characteristics, such as threshold voltage variability, may not be unduly influenced by the barrier layer 220, or any material diffusing therefrom towards the gate dielectric material 218A during the further processing of the device 200. In other cases, a respective “contamination” of the zone 215Z by material of the layer 220 may be taken into consideration when designing the device 200. For this purpose, the high temperature behavior of material of the layer 220 may be determined on the basis of test measurements in which well-established analysis techniques, such as cross-sectional analysis and the like, may be used. For example, for the above-specified materials, a thickness of the layer 220 may range from approximately one to several nm. In other illustrative embodiments, the deposition process 222 may include sophisticated self-limiting deposition techniques in which an appropriate precursor material may prepare the exposed surface so as to obtain a self-limiting surface reaction during a subsequent deposition step. In this case, a precisely defined layer thickness at 1 nm and less may be achieved, if required.

FIG. 2d schematically illustrates the semiconductor device 200 during a further deposition process 223, during which the gate electrode material 215A may be completed, for instance, by depositing an additional layer 215B on the barrier layer 220. The material 215B may represent the same material as used in the zone 215Z, or may be of a different composition, depending on the overall process strategy. By appropriately selecting a thickness of the layer 215B, the overall thickness or height of a gate electrode structure may be defined, while the characteristics of a transistor with respect to threshold voltage for given other transistor dimensions may be substantially determined by the zone 215Z. In some illustrative embodiments, the material layer 215B may be deposited as an intrinsically doped material, which may be accomplished by first depositing the layer 215B including a first type of dopant species, removing an unwanted portion thereof, depositing a further material layer including a second type of dopant species and removing any excess material, thereby providing the desired substantially planar surface topography. In some illustrative embodiments, the barrier layer 220 may also be used as an etch stop material during the removal of an unwanted portion of the layer 215B, so that a thickness of the layer 220 may be appropriately selected in order to provide the desired etch stop capabilities and the required diffusion hindering effect, even if a certain amount of material may be consumed during the etch process. In other illustrative embodiments, the material 215B may be provided in a substantially non-doped state and the required dopant concentration in the gate electrode material 215A may be established on the basis of implantation processes.

FIG. 2e schematically illustrates the semiconductor device 200 in a further advanced manufacturing stage. As illustrated, a transistor 210 may comprise a gate electrode 215 including the corresponding portions 215B, 220, 215Z of the gate electrode material 215A (see FIG. 2d). The gate electrode 215 may be formed by applying well-established photolithography techniques, which may include the deposition of any anti-reflective coating (ARC) materials (not shown), followed by the deposition of photosensitive resist material, which may then be exposed and developed and appropriately trimmed in order to obtain an appropriate etch mask for patterning the gate electrode 215. During a corresponding etch process, well-established etch chemistries may be used, for instance on the basis of hydrogen bromide and the like when the portion 215B is substantially comprised of polysilicon material. In some illustrative embodiments, the material of the barrier layer 220 may be selected such that it may be etched by etch chemistries which may also be used for patterning the portion 215B. For instance, tungsten, titanium nitride and the like may also exhibit a pronounced removal rate during well-established process recipes used for etching silicon material selectively to, for instance, silicon dioxide or other gate dielectric materials, such as hafnium oxide and the like. Consequently, in this case, a high degree of compatibility with conventional etch patterning techniques may be maintained. In other cases, when the material of the barrier layer 220 may have a significantly different etch behavior compared to material 215B, the layer 220 may be used as an etch control layer, thereby providing enhanced overall process controllability. That is, a reduction of overall etch rate during the patterning of the material 215B upon exposing the barrier layer 220 may be advantageously used for increasing overall etch uniformity before patterning the remaining material of the zone 215Z and exposing the gate dielectric material 218A. Thus, by appropriately selecting the material composition of the barrier layer 220 with respect to a specific etch chemistry used for patterning the layer 215B, the barrier layer 220 may also act as an intermediate etch stop or etch control material, thereby enhancing overall controllability and thus uniformity of the gate electrodes 215. Thereafter, the further processing may be continued, for instance on the basis of well-established process techniques, if a high degree of process compatibility may be required.

FIG. 2f schematically illustrates a cross-sectional view of the device 200, when the transistor 210 is substantially completed. Thus, as illustrated, the transistor 210 may comprise drain and source regions 214 laterally enclosing a channel region 211. The drain and source regions 214 may have any appropriate dopant profile so as to define an effective channel length, as is previously explained with reference to the transistor 110. Furthermore, the gate electrode 215 may have formed on the sidewalls thereof a spacer structure 216 of any appropriate configuration, which may also include two or more individual spacer elements, depending on the required lateral dopant profile of the drain and source regions 214. Furthermore, in the manufacturing stage shown, a metal silicide region 217 may be formed in the drain and source regions 214, which may comprise any appropriate metal species, such as nickel, platinum and the like, depending on the overall requirements. Similarly, the gate electrode 215 may comprise a metal silicide 219, which may extend to the barrier layer 220, while a significant concentration of the metal species, such as nickel within the zone 215Z, may be significantly reduced, as previously explained. Consequently, the threshold characteristics may be substantially determined for a given length of the gate electrode 215 and a desired configuration of the drain and source regions 214 by the zone 215Z, in combination with the gate insulation layer 218, with a reduced influence of any metal species used for forming the metal silicide regions 219.

The semiconductor device 200 as shown in FIG. 2f may be formed on the basis of the following processes. Starting from the manufacturing stage as shown in FIG. 2e, exposed portions of the gate dielectric material 218A may be removed or not, depending on the overall process strategy and on the characteristics of the material 218A. Thereafter, appropriate implantation processes may be performed in order to form a first portion of the drain and source regions, such as extension regions and the like, followed by forming one or more spacer elements of the structure 216, which may then be used in combination with the gate electrode 215 as an implantation mask. Next, anneal processes may be performed in order to activate the dopant species in the drain and source regions 214 and the gate electrode 215 and also to re-crystallize implantation-induced damage. As previously explained, during the corresponding high temperature treatments, the final characteristics of the zone 215Z may be adjusted, depending on the overall characteristics of the barrier layer 220. Next, the device 200 may be prepared for an appropriate silicidation sequence, which may comprise appropriate well-established techniques for individually forming the metal silicide regions 217 and 219, while, in other cases, both metal silicide regions may be formed in a common manufacturing sequence. For example, as previously explained with reference to the device 100, an appropriate refractory metal, such as nickel, platinum and the like, or a combination thereof, may be formed above the transistor 210 and a heat treatment may be carried out so as to initiate a chemical reaction including a diffusion of the metal into exposed silicon-containing areas of the drain and source regions 214 and into the gate electrode 215. Due to the “inhomogeneities” created by the barrier layer 220, the diffusion of metal into the zone 215Z may at least be significantly reduced, thereby substantially confining the metal silicide to the portion 215B. Consequently, enhanced uniformity of the transistor 210 with respect to the configuration of the gate electrode 215 may be achieved and may also be maintained during the further processing of the device 200, which may include additional treatments with increased temperature, such as the deposition of an interlayer dielectric material and the like.

As previously explained, the barrier layer 220 may be provided in the form of other material differences, such as a different degree of dopant concentration, which may also have a significant influence on the overall diffusivity of the metal species under consideration.

FIG. 2g schematically illustrates a cross-sectional view of the device 200 in an early manufacturing stage, in which the gate electrode material 215A may be exposed to an ion implantation process 224 in order to form the barrier layer 220 at an appropriate target height level, as previously explained. In some illustrative embodiments, the implantation process 224 may be performed on the basis of an inert or non-doping species, such as xenon, nitrogen and the like, wherein appropriate process parameters, such as implantation dose, energy and the like may be selected to position the ion concentration at the desired height level. For example, a maximum concentration of the barrier layer 220 may range from 10¹⁶-10¹⁹ atoms per cm³ for nitrogen or any other inert species, which may generally exhibit a reduced diffusion activity. Thus, the distribution created during the implantation process 224 for defining the barrier layer 220 may remain localized during the further processing of the device 200 and may therefore provide the desired diffusion hindering effect during the silicidation sequence for forming the metal silicide region 219 (see FIG. 2f). It should be appreciated that, during the silicidation process, a certain degree of penetration of the barrier layer 220 may occur, however at a significantly reduced rate compared to a conventional non-treated polysilicon material, thereby providing a desired overall conductivity of the barrier layer 220, while nevertheless achieving a desired reduction of populating the zone 215Z by the metal species used during the silicidation sequence. In other illustrative embodiments, the implantation process 224 may be designed such that a high concentration of electrically active dopant species may be incorporated, such as an N-type species or a P-type species, depending on the type of transistor to be formed in and above the semiconductor layer 202. In this case, the implantation process 224 may represent a phase or implantation step during a sequence for incorporating a desired dopant species in order to establish an overall desired enhanced conductivity in the gate electrode material 215A, as previously explained. During the step 224, a desired high concentration of, for instance, approximately 10¹⁹-10²⁰ may be created, wherein a maximum concentration may be centered around the desired target height level. During subsequent high temperature processes, the dopant distribution of the layer 220 may be blurred, depending on the overall process parameters during the corresponding anneal processes, but may yet provide a moderately steep dopant gradient at the layer 220. It should be appreciated that the corresponding diffusion hindering effect may be less pronounced compared to a more “abrupt” modification of the materials within the electrode material 215A, for instance by providing a different material composition, but may nevertheless provide enhanced controllability and thus uniformity during the silicidation process. After forming the barrier layer 220 on the basis of the implantation process 224, the further processing may be continued, as previously explained with reference to FIGS. 2e and 2f.

FIG. 2h schematically illustrates the semiconductor device 200 in a manufacturing stage in which material of the zone 215Z has been deposited, as is also previously explained with reference to FIG. 2a. Furthermore, a surface treatment 225 may be performed in an appropriate ambient in order to create the barrier layer 220. For example, an appropriate diffusion hindering species may be incorporated into the surface of the zone 215Z during the treatment 225, for instance in the form of a plasma treatment, in order to modify the surface characteristics and to obtain the barrier layer 220. In some embodiments, the treatment 225 in the form of a plasma treatment may be used to incorporate a species such as nitrogen and the like in order to provide a nitrogen-enriched silicon material of the layer 220, which may have a diffusion blocking effect during the further processing while nevertheless providing a desired minimum conductivity during the silicidation process. That is, the barrier layer 220 may be provided with a reduced thickness in the range of several nm and less, thereby reducing the diffusion of metal species into the zone 215Z on the one hand, but enabling metal silicide to be formed within the barrier layer 220 in order to obtain an electrical connection within the corresponding gate electrode. Similarly, in other illustrative embodiments, the surface treatment 225 may be performed as an oxidizing process in which a desired low amount of oxygen may be incorporated into the zone 215Z in a highly controllable manner, thereby also creating a respective degree of discontinuity of the material characteristics in the gate electrode. In still other illustrative embodiments, a metal species, such as tungsten, titanium, tantalum and the like, may be incorporated during the treatment 225 in order to form the barrier layer 220.

Thereafter, the further processing may be continued by depositing a further portion of the gate electrode material and patterning the same, as is described above.

As a result, the present disclosure provides semiconductor devices and methods for forming the same in which uniformity of a metal silicide in a silicon-containing gate electrode may be enhanced by positioning a diffusion hindering material or barrier layer at an appropriately selected height level, thereby enhancing overall conductivity while not unduly influencing threshold voltage characteristics and leakage current behavior of sophisticated transistor elements. The barrier layer may be formed by deposition and/or implantation and/or surface treatment, thereby providing a high degree of flexibility in incorporating the desired barrier material into the gate electrode structure.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a silicon-containing gate electrode formed above at least a semiconductor region, said silicon-containing gate electrode comprising a first layer comprised of polysilicon and a second layer comprising a metal silicide material, said first and second layers being separated by a barrier material; and
an insulation layer positioned between said silicon-containing gate electrode and said semiconductor region.

2. The semiconductor device of claim 1, wherein said metal silicide comprises nickel.

3. The semiconductor device of claim 1, wherein said barrier material comprises a metal.

4. The semiconductor device of claim 3, wherein said barrier material comprises at least one of tungsten, titanium and cobalt.

5. The semiconductor device of claim 1, wherein said barrier material comprises a doped semiconductor material.

6. The semiconductor device of claim 1, wherein said gate electrode has a length of approximately 50 nm or less.

7. The semiconductor device of claim 6, wherein said length is approximately 30 nm or less.

8. A method, comprising:
identifying a target depth of a metal silicide region to be formed in a silicon-containing gate electrode;
forming said silicon-containing gate electrode above a semiconductor region so as to include a barrier material at said target depth; and
forming said metal silicide region in said silicon-containing gate electrode above said barrier material.

9. The method of claim 8, wherein forming said silicon-containing gate electrode comprises forming a first silicon-containing electrode layer, forming said barrier material on said first silicon-containing electrode layer and forming a second silicon-containing electrode layer.

10. The method of claim 9, wherein forming said barrier material on said first silicon-containing layer comprises depositing a conductive material on said first silicon-containing electrode layer having a higher diffusion blocking effect with respect to a metal used for forming said metal silicide region.

11. The method of claim 10, wherein said conductive material comprises a metal.

12. The method of claim 11, wherein said metal comprises at least one of tungsten and titanium.

13. The method of claim 9, wherein forming said barrier material on said first silicon-containing layer comprises incorporating a barrier species through a surface of said first silicon-containing layer.

14. The method of claim 13, wherein said barrier species is incorporated by performing a plasma treatment.

15. The method of claim 8, wherein forming said silicon-containing gate electrode comprises forming a silicon-containing layer and incorporating a barrier species by performing an ion implantation process so as to form said barrier material.

16. The method of claim 8, wherein said metal silicide region is formed by using nickel.

17. A method, comprising:
forming a layer stack above at least a semiconductor region, said layer stack comprising a first silicon-containing layer, a second silicon-containing layer formed above said first silicon-containing layer and a barrier layer positioned between said first and second silicon-containing layers;
forming a gate electrode from said layer stack; and
forming a metal silicide in said gate electrode.

18. The method of claim 17, wherein forming said layer stack comprises depositing said barrier layer on said first silicon-containing layer and depositing said second silicon-containing layer on said barrier layer.

19. The method of claim 17, wherein said metal silicide is formed on the basis of nickel.

20. The method of claim 17, wherein said barrier layer is provided as a metal-containing material.
